(19) United States
(12) Patent Application Publication
(10) Pub. No.: US 2012/0141766 A1
(43) Pub. Date: Jun. 7, 2012

(54) BIAXIALLY ORIENTED CAVITATED POLYLACTIC ACID FILM

(75) Inventors: Claudio M. Paulino, South Kingstown, RI (US); Nao Yokota, North Kingstown, RI (US)

(73) Assignee: TORAY PLASTICS (AMERICA), INC., N. Kingstown, RI (US)

(21) Appl. No.: 13/313,567

(22) Filed: Dec. 7, 2011

Related U.S. Application Data
(60) Provisional application No. 61/420,575, filed on Dec. 7, 2010.

(51) Int. Cl. B32B 27/36; B32B 27/06; C23C 16/44; C08L 25/06; B29C 47/14; B29C 47/06; B32B 3/10; C08L 67/04

(52) U.S. Cl. 428/304.4; 428/458; 428/480; 525/190; 264/177.17; 264/173.16; 264/173.12; 427/250

(57) ABSTRACT

Disclosed are biaxially oriented laminate films including a core layer including a blend of crystalline polylactic acid polymer and crystalline polystyrene. The films are biaxially oriented at low transverse direction orientation temperatures to impart a degree of cavitation around the crystalline polystyrene such that a white opaque cavitated appearance and lower film densities are obtained. The laminate films may further have additional layers such as a heat sealable layer disposed on one side of the core layer including an amorphous polylactic acid resin and/or a polylactic acid resin-containing layer disposed on the side of the core layer opposite the heat sealable layer, a metal layer, or combinations thereof.

### CROSS-REFERENCE TO RELATED APPLICATION

This application claims the benefit of U.S. Provisional Application Ser. No. 61/420,575, filed Dec. 7, 2010, the entire content of which is incorporated herein by reference.

### FIELD OF INVENTION

This invention relates to a multi-layer biaxially oriented polylactic acid (BOPLA) film with a novel formulation and process that exhibits lower density and optical properties. This improved cavitated formulation includes a blend of crystalline and amorphous PLA resins with an amount of crystalline polystyrene (PS) to achieve a cavitated white opaque PLA-based film that still exhibits degradability and compostability with lower density.

### BACKGROUND OF INVENTION

Biaxially oriented polypropylene films used for packaging, decorative, and label applications often perform multiple functions. In a lamination they can provide printability, transparent or matte appearance, and/or slip properties; they sometimes provide a surface suitable for receiving organic or inorganic coatings for gas and moisture barrier properties; they sometimes provide a heat sealable layer for bag forming and sealing, or a layer that is suitable for receiving an adhesive either by coating or laminating.

However, in recent years, interest in “greener” packaging has been strongly developing. Packaging materials based on biologically derived polymers are increasing due to concerns with renewable resources, raw materials, and greenhouse gases. Bio-based polymers are believed—once fully scaled-up—to help reduce reliance on petroleum, reduce production of greenhouse gases, and can be biodegradable as well. Bio-based polymers such as polylactic acid (PLA)—which is currently derived from corn starch (but can be derived from other plant sugars) and thus, can be considered to be derived from a renewable resource—is one of the more popular and commercially available materials available for packaging film applications. Other bio-based polymers scaling up are PHAs—polyhydroxy alkanoates—which are also of commercial interest.

For bio-based polymer films to be fit-for-use for many snack food packaging applications, it is desirable that the bio-based polymer films match as many of the attributes possible that BOPP is well-known for, such as heat sealability, printability, controlled COF, metallizability, barrier, etc. A disadvantage that PLA films have in comparison to PP films is due to the higher density of PLA vs. PP: about 1.24 for PLA vs. 0.905 for PP. This means that a BOPLA film of the same thickness as a BOPP film will have a much lower yield—a term commonly used in the industry denoting a unit area per unit weight of the film—than the BOPP film. For example, a 20 μm (80 G) thick BOPLA film would have a yield of about 28,000 in²/lb (39.8 m²/kg) vs. a 20 μm (80 G) BOPP film's yield of about 38,300 in²/lb (54.5 m²/kg). The difference in yield is due to the density difference between PLA and PP resin. This significantly reduced yield for BOPLA for a given film thickness makes BOPLA films much more costly to use when replacing BOPP film applications. Moreover, the cost of PLA resin is higher than PP to begin with. At the time of this writing, PLA resin is about 35-50% higher in cost.

One way to make BOPLA films more cost-competitive to BOPP films is to reduce the density of the BOPLA film which then improves its yield. One way to reduce density is via cavitation of the BOPLA film. However, the choice of cavitating agent can make an effect on film cost and density as well. Some mineral-based cavitating agents such as CaCO₃ or talc have a higher density (about 2.7-2.8 for calcium carbonate and 2.75 for talc) than that of PLA, so adding CaCO₃ or other mineral cavitators to the PLA film can offset the density reduction obtained by the cavitation. Moreover, due to the typically large variation in particle sizes, the voids or cavities produced around the mineral cavitating agent are often very large, irregularly shaped, and can adversely affect the mechanical and/or tear resistance properties of the film.

In addition, opaque or white opaque films are often desirable for certain packaging applications for aesthetic reasons. Such films provide a different appearance to the inside of the package when opened by the consumer (white look). A high opacity is also usually desirable so as to provide hiding power over the product, printing, or other laminate films; light or UV protection; or brighter white appearance.

EP Patent 1385899 describes a sequentially biaxially oriented film composed of at least one layer including an aliphatic hydroxycarboxylic acid (i.e. PLA) and 0.5-30 wt % of a cyclic olefin copolymer (COC) having a Tg of 70-270° C. with the film having vacuole-like cavities and a density of less than 1.25 g/cm³. However, the use of COC adds cost to the film as this material is expensive to use.

EP Patent 01385899 describes a multi-layer film design using a PLA base layer formulated with a cyclic polyolefin copolymer (COC) as a cavitating agent to produce an opaque biaxially oriented PLA film. However, this invention uses a cavitating agent that can be costly to use.

U.S. patent application Ser. No. 12/444,420 describes an opaque simultaneously biaxially oriented PLA film composed of at least one layer including a polymer of hydroxycarboxylic acid (i.e. PLA) and 0.5-30 wt % of a cyclic olefin copolymer (COC) having a Tg of 70-270° C. This application states that COC polymers are “the only known effective vacuole formers in biaxially oriented PLA films.” Moreover, the use of COC as a cavitating agent adds cost to the film as COC materials are expensive and costly to begin with.

U.S. patent application Ser. No. 12/483,072 describes a method of producing matte and opaque biaxially oriented PLA films using inorganic antiblock particles and processing conditions. The inorganic particles can be high in density and can result in large voids that may affect mechanical properties adversely.

### SUMMARY OF THE INVENTION

The inventors seek to develop alternate polymeric cavitating agents to address the above issues of making opaque cavitated BOPLA films, either by sequential or simultaneous orientation and reduce cost of such cavitated BOPLA film. The inventors have found a solution that utilizes crystalline polystyrene which has a similar density to COC (1.04 vs. 1.02) and a Tg of 95° C. The use of polystyrene as a cavitating agent allows good cavitation and opacity, increases the overall film yield vs. using mineral-type cavitating agents, maintains good mechanical properties, and is a lower cost polymeric cavitating agent than expensive COC polymers. This invention provides formulations that accomplish this goal as well as maintaining the biodegradability of the BOPLA film. It is also contemplated to use this formulation as part of a metallized opaque BOPLA film.

One embodiment is a biaxially oriented polylactic acid polymer film including at least one layer including polylactic acid resin and 2.0-10.0 wt % crystalline polystyrene. The layer including polylactic acid resin and crystalline polystyrene has a plurality of voids and cavities and a density of less than 1.24. The film may have a white opaque appearance. A metal layer may be deposited on one side of the layer including polylactic acid resin and crystalline polystyrene. The metal layer may have an optical density of 2.0-4.0, and may include aluminum. Preferably, the film has an oxygen gas barrier of less than 46.5 cc/m²/day and moisture vapor barrier of less than 5 g/m²/day more preferably, the film has an oxygen gas barrier of less than 10 cc/m²/day and moisture vapor barrier of less than 1.5 g/m²/day.

One embodiment is a multi-layer laminate film including a first layer of a heat sealable resin including an amorphous PLA resin and a second layer including a substantially crystalline PLA resin-containing blend on one side of the sealable amorphous PLA layer. This second crystalline PLA resin-containing blend layer could be considered a core or base layer to provide the bulk strength of the laminate film. The second PLA core layer includes a blend of crystalline PLA homopolymer combined with an amount of crystalline polystyrene in the amount of about 2.0-10.0 wt % of this layer that acts as a cavitating agent to achieve a cavitated white opaque appearance and density reduction of the PLA film. An optional amount of ethylene-acrylate copolymer can also be added to the core layer at about 2-10 wt % of the core layer that acts as a processing aid to enable high transverse orientation rates of 8-11×.orientation. The second PLA core layer also could include inorganic antiblock particles of suitable size, selected from amorphous silicas, aluminosilicates, sodium calcium aluminum silicates, crosslinked silicone polymers, and/or polymethylmethacrylates. Suitable amounts range from 0.03-5.0% by weight of the core layer and typical particle sizes of 3.0-6.0 μm in diameter. Such antiblock particles function to control coefficient of friction properties, enable web-handling, and prevent blocking of the film. The second PLA core layer may also include an optional amount of amorphous PLA blended with the crystalline PLA.

The first heat sealable layer includes an amorphous PLA resin which provides heat sealable properties to the laminate and also may include various additives such as antiblock particles to allow for easier film handling. Furthermore, the laminate could further include a third PLA resin-containing layer on the second PLA resin-containing core layer opposite the side with the amorphous PLA sealable layer for use as a printing layer or metal receiving layer or coating receiving layer. This third layer of this laminate can include, for example, either an amorphous PLA or a crystalline PLA, or blends thereof.

Preferably, the second PLA resin-containing core layer includes a crystalline polylactic acid homopolymer of about 90-100 wt % L-lactic acid units (or 0-10 wt % D-lactic acid units) combined with an amount of crystalline polystyrene in the amount of about 2.0-10.0 wt % of this layer that acts as a cavitating agent to achieve a cavitated white opaque appearance and density reduction of the PLA film. An optional amount of amorphous PLA may also be blended in with the crystalline PLA from 0-48 wt % of the core layer. The amorphous PLA is also based on L-lactic acid units but has greater than 10 wt % D-lactic acid units and/or meso-lactide units (which includes one each of L and D lactic acid residuals). An optional amount of ethylene-acrylate copolymer can also be added to the core layer at about 2-10 wt % of the core layer as a process aid for orientation, particularly transverse orientation. The core layer preferably includes antiblock particles of suitable size, selected from amorphous silicas, aluminosilicates, sodium calcium aluminum silicates, crosslinked silicone polymers, and/or polymethylmethacrylates to control coefficient of friction (COF) properties. Suitable amounts range from 0.03-5.0% by weight of the core layer, preferably 0.05-0.50 wt % (500-5000 ppm) and typical particle sizes of 3.0-6.0 μm in diameter. Migratory slip additives may also be contemplated to control COF properties such as fatty amides (e.g. erucamide, stearamide, oleamide, etc.) or silicone oils ranging from low molecular weight oils to ultra high molecular weight gels. Suitable amounts of slip additives to use can range from 300 ppm to 10,000 ppm of the layer.

Preferably, the first PLA heat sealable resin-containing layer includes an amorphous PLA of greater than 10 wt % D-lactic acid units. This first heat sealable amorphous PLA resin-containing layer can also include an antiblock component selected from amorphous silicas, aluminosilicates, sodium calcium aluminum silicates, crosslinked silicone polymers, and polymethylmethacrylates to aid in machinability and winding and to lower coefficient of friction (COF) properties. Suitable amounts range from 0.03-0.5% by weight of the heat sealable layer and typical particle sizes of 3.0-6.0 μm in diameter, depending on the final thickness of this layer. Migratory slip additives may also be contemplated to control COF properties such as fatty amides (e.g. erucamide, stearamide, oleamide, etc.) or silicone oils ranging from low molecular weight oils to ultra high molecular weight gels. Suitable amounts of slip additives to use can range from 300 ppm to 10,000 ppm of the layer.

Another embodiment could have this first PLA resin-containing layer include a non-heat-sealable amorphous PLA such as a crystalline PLA resin similar to that used in the second PLA resin-containing core layer. In addition, various blends of amorphous and crystalline PLA can be contemplated at similar ratios as described for the core layer. In the case that a crystalline PLA is used or a blend including crystalline PLA, an optional amount of the ethylene-acrylate copolymer process aid could be used, again in the amount of 2-10 wt % of this layer to enable transverse orientation at high rates. Preferably, this layer will also contain antiblock particles selected from amorphous silicas, aluminosilicates, sodium calcium aluminum silicates, crosslinked silicone polymers, and polymethylmethacrylates to control COF properties and aid in machinability and winding. Suitable amounts range from 0.03-0.5% by weight of the core layer and typical particle sizes of 3.0-6.0 μm in diameter, depending on the final thickness of this layer. Migratory slip additives may also be contemplated to control COF properties such as fatty amides (e.g. erucamide, stearamide, oleamide, etc.) or silicone oils ranging from low molecular weight oils to ultra high molecular weight gels, or blends of fatty amides and silicone oil-based materials. Suitable amounts of slip additives to use can range from 300 ppm to 10,000 ppm of the layer.

In yet another embodiment, the second PLA resin-containing core layer could be extruded by itself as a single layer only. As mentioned previously, this layer includes a crystalline polylactic acid homopolymer of about 90-100 wt % L-lactic acid units (or 0-10 wt % D-lactic acid units) combined with an amount of crystalline polystyrene in the amount of about 2.0-10.0 wt % of this layer that acts as a cavitating agent to achieve a cavitated white opaque appearance and density reduction of the PLA film. An optional amount of amorphous PLA may also be blended in with the crystalline PLA from 0-48 wt % of the core layer. The amorphous PLA is also based on L-lactic acid units but has greater than 10 wt % D-lactic acid units and/or meso-lactide units (which includes one each of L and D lactic acid residuals). An optional amount of ethylene-acrylate copolymer can also be added to the core layer at about 2-10 wt % of the core layer as a process aid for orientation, particularly transverse orientation. Optionally added to the core layer are antiblock particles of suitable size, selected from amorphous silicas, aluminosilicates, sodium calcium aluminum silicates, crosslinked silicone polymers, and/or polymethylmethacrylates to control coefficient of friction (COF) properties. Suitable amounts range from 0.03-5.0% by weight of the core layer, preferably 0.05-0.50 wt %, and typical particle sizes of 3.0-6.0 μm in diameter. Migratory slip additives may also be contemplated to control COF properties such as fatty amides (e.g. erucamide, stearamide, oleamide, etc.) or silicone oils ranging from low molecular weight oils to ultra high molecular weight gels. Suitable amounts of slip additives to use can range from 300 ppm to 10,000 ppm of the layer.

In the case where the above embodiments are to be used as a substrate for vacuum deposition metallizing, it is recommended that migratory slip additives not be used as these types of materials may adversely affect the metal adhesion or metallized gas barrier properties of the metallized BOPLA film. It is thought that as the hot metal vapor condenses on the film substrate, such fatty amides or silicone oils on the surface of the film could vaporize and cause pin-holing of the metal-deposited layer, thus compromising gas barrier properties. Thus, only non-migratory antiblock materials should be used to control COF and web-handling.

In the case where the above embodiments are to be used as a printing film, it may be advisable to avoid the use of silicone oils, in particular low molecular weight oils, as these may interfere with the print quality of certain ink systems used in process printing applications. However, this depends greatly upon the ink system and printing process used.

For these film embodiments described above, it is preferable to discharge-treat one side of the film. For the multi-layer film embodiments, it is preferable to discharge-treat the side opposite the heat sealable first layer for lamination, metallizing, printing, or coating. In the case of a 2-layer laminate structure wherein the amorphous PLA sealable layer is contiguous with a cavitated crystalline PLA core layer, it is preferable to discharge-treat the side of the core layer opposite the sealable layer for purposes of laminating, printing, metallizing, coating, etc. In the case of a 3-layer laminate structure, it is preferable to discharge-treat the side of the third layer which is contiguous to the side of the core layer opposite the heat sealable first layer. This third layer, as mentioned previously, is often formulated with materials that are conducive to receiving printing inks, metallizing, adhesives, or coatings. In the case of a single layer film, either or both sides of the film can be discharge-treated as desired.

Discharge-treatment in the above embodiments can be accomplished by several means, including but not limited to corona, flame, plasma, or corona in a controlled atmosphere of selected gases. Preferably, in one variation, the discharge-treated surface has a corona discharge-treated surface formed in an atmosphere of CO₂ and N2 to the exclusion of O₂. The laminate film embodiments could further comprise a vacuum-deposited metal layer on the discharge-treated layer's surface. Preferably, the metal layer has a thickness of about 5 to 100 nm, has an optical density of about 1.5 to 5.0, and includes aluminum, although other metals can be contemplated such as titanium, vanadium, chromium, manganese, iron, cobalt, nickel, copper, zinc, gold, or palladium, or alloys or blends thereof.

Preferably, the laminate film is produced via coextrusion of the heat sealable layer and the blended core layer and other layers if desired, through a compositing die whereupon the molten multilayer film structure is quenched upon a chilled casting roll system or casting roll and water bath system and subsequently oriented in the machine and/or transverse direction into an oriented multi-layer film. Machine direction orientation rate is typically 2.0-3.0× and transverse direction orientation—with the use of the ethylene-acrylate impact modifier process aid—is typically 8.0-11.0×. Otherwise, without the ethylene-acrylate impact modifier process aid, transverse direction orientation may be limited to a lower rate, typically 3.0-6.0×. Heat setting conditions in the TDO oven is also critical to minimize thermal shrinkage effects.

For example, a multi-layer BOPLA film was made using a 1.5-meter wide sequential orientation line process via coextrusion through a die, cast on a chill drum using an electrostatic pinner, oriented in the machine direction through a series of heated and differentially sped rolls, followed by transverse direction stretching in a tenter oven. The multilayer coextruded laminate sheet is coextruded at processing temperatures of ca. 170° C. to 230° C. through a die and cast onto a cooling drum whose surface temperature is controlled between 15° C. and 26° C. to solidify the non-oriented laminate sheet at a casting speed of about 13-17 mpm. The non-oriented laminate sheet is stretched in the longitudinal direction at about 60° C. to 70° C. at a stretching ratio of about 2 to about 3 times the original length and the resulting stretched sheet is annealed at about 45° C. to 55° C. to obtain a uniaxially oriented laminate sheet. The uniaxially oriented laminate sheet is introduced into a tenter at a linespeed of ca. 40 to 60 mpm and preliminarily heated between about 65° C. and 75° C., and stretched in the transverse direction at about 75° C. to 90° C. at a stretching ratio of about 3-10 times the original width and then heat-set or annealed at about 90° C. to 135° C. to reduce internal stresses due to the orientation and minimize shrinkage and give a relatively thermally stable biaxially oriented sheet.

To enable the cavitation process, it is preferable to transversely stretch the laminate film at a relatively low temperature, preferably 75-80° C. for the given linespeed. Transverse direction orientation rate is preferably 3-10 times, more preferably 6-10 times using the optional ethylene-acrylate process aid or, if not using the processing aid, more preferably at 4-6 times. To render a film that is more opaque in appearance, it is preferable to increase the machine direction orientation, preferably about 3.0 times the original length. To render the film less opaque in appearance, it is preferable to decrease the machine direction orientation, preferably about 2.4 times the original length.

All these examples can also be metallized via vapor-deposition, preferably a vapor-deposited aluminum layer, with an optical density of at least about 1.5, preferably with an optical density of about 2.0 to 4.0, and even more preferably between 2.3 and 3.2.

Optionally, an additional third layer specifically formulated for metallizing to provide adequate metal adhesion, metal gloss, and gas barrier properties can be disposed on the second PLA resin-containing core layer, opposite the side with the heat sealable layer. Additionally, this additional layer's surface may also be modified with a discharge treatment to make it suitable for metallizing, laminating, printing, or converter applied adhesives or other coatings. It can also be contemplated to add a gas barrier layer contiguously attached to one side of the multi-layer film which can also then act as the metal-receiving layer. Such a gas barrier layer can improve the gas and moisture transmission rate of the cavitated PLA film. Gas barrier layers can include, but are not limited to: ethylene vinyl alcohols, polyvinyl alcohols, polyvinyl amines, polyhydroxyaminoethers, amorphous copolyesters, or blends thereof.

This invention provides a method to allow the production of white opaque cavitated BOPLA films using crystalline polystyrene as a cavitation agent at particular orientation rates and temperatures. Such a film method and composition can result in cavitated white opaque, lower density biaxially oriented PLA films that are more economical than the current art for BOPLA.

Additional advantages of this invention will become readily apparent to those skilled in the art from the following detailed description, wherein only the preferred embodiments of this invention are shown and described, simply by way of illustration of the best mode contemplated for carrying out this invention. As will be realized, this invention is capable of other and different embodiments, and its details are capable of modifications in various obvious respects, all without departing from this invention. Accordingly, the examples and description are to be regarded as illustrative in nature and not as restrictive.

### BRIEF DESCRIPTION OF THE DRAWING

FIG. 1 shows compostability studies of Ex 1 and CEx 1 in a mulch medium at 58° C. for several weeks substantially in accordance with ASTM D6400.

### DETAILED DESCRIPTION OF THE INVENTION

Methods for achieving improved opacity and film yield of a PLA-based oriented film using a polymeric cavitating agent and without sacrificing compostability or degradability features of the film and other desirable mechanical properties is provided. By keeping the amount of cavitating agent as a minor component of the film, compostability or degradability properties can be maintained. The film will also retain a high degree of sustainably-sourced materials.

In one embodiment, the laminate film includes a 2-layer coextruded film of: A PLA resin core layer including a crystalline polylactic acid polymer combined with an amount of crystalline polystyrene in the amount of about 2.0-10.0 wt % of this layer that acts as a cavitating agent to achieve a cavitated white opaque appearance and density reduction of the PLA film, optionally blended with an amount of an amorphous PLA polymer, an optional amount of ethylene-acrylate copolymer, and an amount of inorganic antiblock particle; and a heat sealable layer including an amorphous polylactic acid polymer; and the side of the crystalline PLA core layer blend opposite the sealable resin layer is discharge-treated.

Another embodiment of the inventive laminate film includes a similar construction as above, except that a third PLA skin layer may be disposed on the side of the crystalline PLA/inorganic antiblock particle core layer blend opposite the heat sealable amorphous PLA layer. This third PLA layer can include either crystalline PLA resin or amorphous PLA resin or blends thereof. In the case where crystalline PLA resin is part of this layer's formulation, an amount of ethylene-acrylate copolymer can be incorporated as in the core layer formulation. Generally, it is desirable to discharge-treat the exposed surface of this third layer in order to provide further functionality as a surface to receive metallization, printing, coating, or laminating adhesives.

The polylactic acid resin core layer is a crystalline polylactic acid of a specific optical isomer content and can be biaxially oriented. As described in U.S. Pat. No. 6,005,068, lactic acid has two optical isomers: L-lactic acid (also known as (S)-lactic acid) and D-lactic acid (also known as (R)-lactic acid). Three forms of lactide can be derived from these lactic acid isomers: L,L-lactide (also known as L-lactide) and which includes two L-lactic acid residuals; D,D-lactide (also known as D-lactide) and which includes two D-lactic acid residuals; and meso-lactide which includes one each of L and D-lactic acid residuals. The degree of crystallinity is determined by relatively long sequences of a particular residual, either long sequences of L or of D-lactic acid. The length of interrupting sequences is important for establishing the degree of crystallinity (or amorphous) and other polymer features such as crystallization rate, melting point, or melt processability. The crystalline polylactic acid resin is preferably one including primarily of the L-lactide isomer with minority amounts of either D-lactide or meso-lactide or combinations of D-lactide and meso-lactide. Preferably, the minority amount is D-lactide and the amount of D-lactide is 10 wt % or less of the crystalline PLA polymer. More preferably, the amount of D-lactide is less than about 5 wt %, and even more preferably, less than about 2 wt %. Suitable examples of crystalline PLA for this invention are Natureworks® Ingeo™ 4042D and 4032D. These resins have relative viscosity of about 3.9-4.1, a melting point of about 165-173° C., a crystallization temperature of about 100-120° C., a glass transition temperature of about 55-62° C., a D-lactide content of about 4.25 wt % and 1.40 wt % respectively, density of about 1.25 g/cm³, and a maximum residual lactide in the polylactide polymer of about 0.30% as determined by gas chromatography. Molecular weight M_{w} is typically about 200,000; Mₙ typically about 100,000; polydispersity about 2.0. Natureworks® 4032D is the more preferred crystalline PLA resin, being more crystalline than 4042D and more suitable for high heat biaxial orientation conditions. In addition, the 4042D PLA grade contains about 1000 ppm of erucamide and for some applications, particularly for gas barrier metallizing, may not be suitable.

The core resin layer is typically 8 μm to 100 μm in thickness after biaxial orientation, preferably between 10 μm and 50 μm, and more preferably between about 15 μm and 25 μm in thickness. A preferred embodiment is to use the higher crystalline, higher L-lactide content PLA (lower wt % D-lactide of about 1.40) such as Natureworks® 4032D.

The core layer can also optionally include an amount of amorphous PLA resin to improve further extrusion processing and oriented film processing. The addition of amorphous PLA in the core layer helps to lower extrusion polymer pressure and in terms of film manufacturing, helps to reduce or slow crystallization rate of the newly oriented film. This aids in the orientation of the PLA film in both MD and TD and helps reduce defects such as uneven stretch marks. It also helps with the slitting of the biaxially oriented film at the edge-trimming section of the line by reducing the brittleness of the edge trim and reducing the instances of edge trim breaks which can be an obstacle to good productivity. The amorphous PLA is preferably based on a L-lactide isomer with D-lactide content of greater than 10 wt %. A suitable amorphous PLA to use is Natureworks® Ingeo™ 4060D grade. This resin has a relative viscosity of about 3.25-3.75, T_{g} of about 52-58° C., seal initiation temperature of about 80° C., density of about 1.24 g/cm³, a D-lactide content of about 12 wt %, and a maximum residual lactide in the polylactide polymer of about 0.30% as determined by gas chromatography. Molecular weight M_{w} is about 180,000. Suitable amounts of amorphous PLA to use in the core are concentrations of up to about 48 wt % of the core layer, preferably up to about 30 wt % of the core layer, and even more preferably about 15-20 wt % of the core layer. It should be noted, however, that too much amorphous PLA in the core layer (e.g. 50% or greater) can cause high thermal shrinkage rates after biaxial orientation and in spite of heat-setting conditions in the transverse orientation oven to make a thermally stable film. A thermally, dimensionally stable film is important if the substrate is to be used as a metallizing, printing, coating, or laminating substrate. (However, if the BOPLA is desired as a shrinkable film, this composition and appropriate processing conditions might be suitable.)

An optional component of the invention is blending into the core layer a minority amount of ethylene-acrylate copolymer as a processing aid in orientation, in particular, to enable high transverse orientation rates (TDX) similar to that used in BOPP orientation (e.g. 8-10 TDX). Ethylene-acrylates are of the general chemical formula of CH₂═C(R¹)CO₂R² where R¹ can be hydrogen or an alkyl group of 1-8 carbon atoms and R2 is an alkyl group of 1-8 carbon atoms. Ethylene-acrylate copolymers contemplated for this invention can be based on ethylene-acrylate, ethylene-methacrylate, ethylene-n-butyl acrylate-glycidyl methacrylate, ethylene-glycidyl methacrylate, ethylene-butyl-acrylate, ethylene acrylic esters, or blends thereof. Ethylene vinyl acetate (EVA) and ethylene methacrylate (EMA) can also be contemplated. Other similar materials may also be contemplated. As described in U.S. Pat. No. 7,354,973, suitable compositions of the ethylene-acrylate copolymers can be about 20-95 wt % ethylene content copolymerized with about 3-70 wt % n-butyl acrylate and about 0.5-25 wt % glycidyl methacrylate monomers. A particularly suitable ethylene-acrylate copolymer of this type is one produced by E. I. DuPont de Nemours and Company Packaging and Industrial Polymers Biomax® Strong 120. This additive has a density of about 0.94 g/cm³, a melt flow rate of about 12 g/10 minutes at 190° C./2.16 kg weight, a melting point of about 72° C., and a glass transition temperature of about −55° C. Other suitable ethylene-acrylate copolymer impact modifiers commercially available are: DuPont Elvaloy® PTW, Rohm & Haas, Inc. BPM500, and Arkema, Inc. Biostrength® 130.

Suitable amounts of ethylene-acrylate copolymer to be blended in the crystalline PLA-including core layer is from 2-10 wt % of the core layer, preferably 2-7 wt % and more preferably, 3-5 wt %. At these concentrations, acceptable clarity of the biaxially oriented film is maintained. Too much ethylene-acrylate may cause haziness; too little may not enable transverse orientation at 8-10×. Blending into the core layer can be done most economically by dry-blending the respective resin pellets; it is contemplated that more aggressive blending such as melt-compounding via single-screw or twin-screw can result in better dispersion of the ethylene-acrylate copolymer throughout the PLA matrix.

To obtain the white opaque cavitated appearance of the oriented PLA film, an amount of about 2.0-10.0 wt % of crystalline polystyrene is added to the core layer of the laminate film, preferably 2.5-5.0 wt %. Adding less than 2 wt % of the crystalline polystyrene will not produce the desired white opaque cavitated appearance and density reduction of the oriented PLA film, and adding more than 10.0 wt % of crystalline polystyrene will adversely affect the biodegradability or compostability of the oriented PLA film. Suitable examples of crystalline polystyrene grades are Ineos Nova™ LLC grade 1290, melt flow rate=1.6 g/10 min, Vicat softening temperature 109° C., specific gravity=1.04; and Ineos Nova™ LLC grade 1291, melt flow rate=1.6 g/10 min, Vicat softening temperature 109° C., specific gravity=1.04. A preferred grade is Ineos Nova™ LLC grade 1600, melt flow rate=6 g/10 min, Vicat softening temperature 106° C., specific gravity=1.04.

An amount of an inorganic antiblock agent can be added in the amount of 300-50,000 ppm (0.03-5.0 wt %) of the core resin layer, preferably 500-5000 ppm, and even more preferably, 1000-2000 ppm. Preferred types of antiblock are spherical sodium aluminum calcium silicates or an amorphous silica of nominal 6 μm average particle diameter, but other suitable inorganic antiblocks can be used including crosslinked silicone polymer or polymethylmethacrylate, and ranging in size from 2 μm to 6 μm. Particularly preferred is spherical sodium aluminum calcium silicate of nominal 3.0 μm diameter size manufactured by Mizusawa Industrial Chemicals under the tradename Silton® JC-30. Silton® JC-30 has typical physical properties of: bulk density of 0.70 g/cm³, average particle size of 2.9 μm, refractive index 1.50, specific surface area 18 m²/g, Hunter brightness of 96%, and oil absorption of 45 ml/100 g.

Without being bound by any theory, it is believed that when the inventive film is biaxially oriented, particularly at relatively low transverse orientation temperatures, cavitation occurs around the crystalline polystyrene domains within the core layer. The degree of cavitation imparts the matte or opaque appearance of the film: at a low degree of cavitation, the film has a matte appearance; at a higher degree of cavitation, the film has an opaque appearance. This cavitation has been observed by changes in measurement of the film's density (Table 1). What is surprisingly found, however, is that using same amounts of cheaper crystalline polystyrene instead of more expensive COC—e.g. 2 to 10 wt % in the PLA core layer—can produce the same degree of cavitation, resulting in a white opaque appearance and lower density PLA film at a much lower cost. In this way, a white opaque cavitated PLA film can be made using inexpensive organic cavitating agents and processing conditions and also maintaining biodegradable or compostability properties.

In the embodiment of a 2-layer coextruded multilayer film, the core resin layer can be surface treated on the side opposite the skin layer with an electrical corona-discharge treatment method, flame treatment, atmospheric plasma, or corona discharge in a controlled atmosphere of nitrogen, carbon dioxide, or a mixture thereof, with oxygen excluded and its presence minimized. The latter method of corona treatment in a controlled atmosphere of a mixture of nitrogen and carbon dioxide is particularly preferred. This method results in a treated surface that includes nitrogen-bearing functional groups, preferably at least 0.3 atomic % or more, and more preferably, at least 0.5 atomic % or more. This treated core layer is then well suited for subsequent purposes of metallizing, printing, coating, or laminating.

In this embodiment of a 2-layer laminate film, it is also possible to add optional amounts of migratory slip agents such as fatty amides and/or silicone oils in the core layer to aid further with controlling coefficient of friction (COF) and web handling issues. Suitable types of fatty amides are those such as stearamide or erucamide and similar types, in amounts of 100-1000 ppm of the core. Preferably, stearamide is used at 400-600 ppm of the core layer. A suitable silicone oil that can be used is a low molecular weight oil of 350 centistokes which blooms to the surface readily at a loading of 400-600 ppm of the core layer. However, if the films of this invention are desired to be used for metallizing or high definition process printing, it is recommended that the use of migratory slip additives be avoided in order to maintain metallized barrier properties and adhesion or to maintain high printing quality in terms of ink adhesion and reduced ink dot gain. In this case, it is recommended that coefficient of friction control and web handling is resolved using inorganic antiblock particles similar to those already described.

The coextruded skin layer can be a heat sealable resin layer including an amorphous polylactic acid polymer. As described earlier, the amorphous PLA is preferably based on a L-lactide isomer with D-lactide content of greater than 10 wt %. A suitable amorphous PLA to use is Natureworks® Ingeo™ 4060D grade. This resin has a relative viscosity of about 3.25-3.75, T_{g} of about 52-58° C., seal initiation temperature of about 80° C., density of about 1.24 g/cm³, a D-lactide content of about 12 wt %, and a maximum residual lactide in the polylactide polymer of about 0.30% as determined by gas chromatography. Molecular weight M_{w} is about 180,000. The preferred amount to be used as a heat sealable skin layer is about 100 wt % of the layer. It is also preferred to add an amount of inorganic antiblock to this layer to aid in web-handling, COF control, film winding, and static control, among other properties. Suitable amounts would be about 1000-5000 ppm of the heat sealable resin layer, preferably 3000-5000 ppm.

Preferred types of antiblock are spherical crosslinked silicone polymer such as Toshiba Silicone's Tospearl® grades of polymethlysilsesquioxane of nominal 2.0 and 3.0 μm sizes. Alternatively, sodium aluminum calcium silicates of nominal 3 μM in diameter can also be used (such as Mizusawa Silton® JC-30), but other suitable spherical inorganic antiblocks can be used including polymethylmethacrylate, silicas, and silicates, and ranging in size from 2 μm to 6 μm. Migratory slip agents such as fatty amides or silicone oils can also be optionally added to the heat seal resin layer of types and quantities mentioned previously if lower COF is desired. However, if the films of this invention are desired to be used for metallizing or high definition process printing, it is recommended that the use of migratory slip additives be avoided or minimized in order to maintain metallized barrier properties and metal adhesion or to maintain high printing quality in terms of ink adhesion and reduced ink dot gain.

A heat sealable resin layer can be coextruded on one side of the core layer, the heat sealable layer having a thickness after biaxial orientation of between 0.5 and 5 μm, preferably between 1.0 and 2.0 μm. The core layer thickness can be of any desired thickness after biaxial orientation, but preferred and useful thicknesses are in the range of 10 μm to 100 μm, preferably 13.5 μm to 25 μm, and even more preferably 15.0 μm-20.0 μm. These film thicknesses, however, are what are considered “polyweight” thicknesses, i.e. the amount of polymer extruded prior to cavitation. The cavitation process increases the physical thickness due to the “lofting” effect of void formation around the cavitating particles. Thus, cavitated film thickness can and should be distinguished between “polyweight” and “cavitated” thickness. In general, cavitated thickness will be measurably and physically thicker than polyweight thickness. For example, a 20 μm polyweight PLA film of this invention can be lofted to a 27.5 μm cavitated PLA film via the voids formed around the polystyrene cavitating agent. The cavitating thickness can be adjusted via processing conditions such as orientation stretching ratios, orientation preheat and stretching temperatures, amount of cavitating agent used, etc. (Of course, those coextruded layers which do not contain any cavitating agent, will not “loft” or cavitate.)

The coextrusion process includes a multi-layered compositing die, such as a two- or three-layer die, or a multi-layer compositing feed block feeding multi extrudate layers to a single layer die. In the case of a 2-layer coextruded film, a two-layer compositing die or a combination of a 2-layer compositing feed block feeding 2 extrudate layers to a single layer die can be used. In the case of a 3-layer coextruded film, the polymer blend core layer can be sandwiched between the heat sealable resin layer and a third layer using a three-layer compositing die. One embodiment is to coextrude in only two layers with only the blended core layer and the heat sealable layer coextruded on one side of the core layer. In this case, the core layer side opposite the heat sealable layer is further modified by adding inorganic antiblock particles into the core layer itself as explained previously and can also be surface-treated via a discharge-treatment method if so desired. In a three-layer coextruded film embodiment, a third layer on the side of the core layer opposite the heat sealable layer can also be modified with antiblock particles in lieu of the core layer and also is surface-treated via a discharge-treatment method as desired. Selection of the third layer can include any polymer typically compatible with the core layer resin such as a crystalline PLA resin, amorphous PLA resin, or blends thereof. Typically, selection of this third layer's formulation is to enhance the coextruded film's printability, appearance, metallizability, winding, laminating, sealability, or other useful characteristics. Useful thickness of this third layer after biaxial orientation can be similar to the polyweight thicknesses cited for the heat sealable skin layer, preferably 1.0-2.0 μm.

The surface opposite the heat sealable layer can be surface-treated if desired with a corona-discharge method, flame treatment, atmospheric plasma, or corona discharge in a controlled atmosphere of nitrogen, carbon dioxide, or a mixture thereof which excludes oxygen. The latter treatment method in a mixture of CO₂ and N₂ only is preferred. This method of discharge treatment results in a treated surface that includes nitrogen-bearing functional groups, preferably 0.3% or more nitrogen in atomic %, and more preferably 0.5% or more nitrogen in atomic %. This discharge-treated surface can then be metallized, printed, coated, or extrusion or adhesive laminated. Preferably, it is printed or metallized, and more preferably, metallized.

If the three-layer coextruded film embodiment is chosen, the third layer may be coextruded with the core layer opposite the heat sealable resin layer, having a polyweight thickness after biaxial orientation between 0.5 and 5 μm, preferably between 0.5 and 3 μm, and more preferably between 1.0 and 2.0 μm. A suitable material for this layer is a crystalline PLA or amorphous PLA or blends thereof, as described earlier in the description. If amorphous PLA is used, the same suitable resin grade used for the heat sealable layer may be employed (e.g. Natureworks® 4060D). If crystalline PLA is used, the same suitable grades as used for the core layer may be employed such as Natureworks® 4042D or 4032D, with the 4032D grade preferred in general. Additionally, blends of both crystalline and amorphous PLA may be contemplated for this layer, similar to previously described formulations for the core layer, but not limited to those descriptions. For example, the ratio of amorphous PLA to crystalline PLA for this third skin layer can range from 0-100 wt % amorphous PLA and 100-0 wt % crystalline PLA. In those embodiments in which crystalline PLA is used in the third layer, an amount of ethylene-acrylate copolymer could be used as described previously, in order to ensure the ability to transversely orient this layer at high orientation rates. Suitable amounts of ethylene-acrylate copolymer to use in this skin layer are 2-10 wt %, preferably 2-7 wt % and, more preferably, 3-5 wt %. The use of various blends of amorphous and crystalline PLA in this layer may make it more suitable for printing, metallizing, coating, or laminating, and the exact ratio of the blend can be optimized for these different applications.

This third layer may also advantageously contain an anti-blocking agent and/or slip additives for good machinability and a low coefficient of friction in about 0.01-0.5% by weight of the third layer, preferably about 250-1000 ppm. Preferably, non-migratory inorganic slip and/or antiblock additives as described previously should be used to maintain gas barrier properties and metal adhesion if metallizing, or ink wetting and ink adhesion if printing.

In addition, another embodiment that can be considered is to replace the heat sealable amorphous PLA layer with a non-sealable PLA layer. In this variation, amorphous or crystalline PLA may be used, or blends thereof. In the case of making this layer non-sealable, preferably crystalline PLA should be used, either by itself or as the majority component of a blend with amorphous PLA. As discussed previously, if crystalline PLA is used for this layer, an amount of ethylene-acrylate copolymer could be used as part of this layer to aid high transverse orientation rates. Suitable amounts of ethylene-acrylate copolymer to use in this skin layer are 2-10 wt %, preferably 2-7 wt % and, more preferably, 3-5 wt %. Preferably, non-migratory inorganic slip and/or antiblock additives as described previously should be used to maintain gas barrier properties and metal adhesion if metallizing, or ink wetting and ink adhesion if printing. It is also preferred to add an amount of inorganic antiblock to this layer to aid in web-handling, COF control, film winding, and static control, among other properties. Suitable amounts would be about 1000-5000 ppm of the this non-eat sealable resin layer, preferably 3000-5000 ppm. Preferred types of antiblock are spherical crosslinked silicone polymer such as Toshiba Silicone's Tospearl® grades of polymethlysilsesquioxane of nominal 2.0 and 3.0 μm sizes. Alternatively, sodium aluminum calcium silicates of nominal 3 μm in diameter can also be used (such as Mizusawa Silton® JC-30), but other suitable spherical inorganic antiblocks can be used including polymethylmethacrylate, silicas, and silicates, and ranging in size from 2 μm to 6 μm. It is often preferred to discharge-treat the exposed side of this layer so as to enable adequate adhesion and wet-out of adhesives or inks or coatings to this side. In particular, cold seal latexes can be applied to this discharge-treat surface.

The multilayer coextruded film of the invention can be made either by sequential biaxial orientation or simultaneous biaxial orientation which are well-known processes in the art. In the case of sequential orientation, a 1.5-meter wide sequential orientation film-making line was used for the forthcoming Examples and Comparative Examples.

Multi-layer BOPLA films were made using a 1.5 m wide sequential orientation line process with a blend of Natureworks® PLA4032D, Natureworks® PLA4060D, cavitating agents (PS and COC polymers and calcium carbonate and talc masterbatches in PLA carrier) as core layer (B) as detailed in the Examples and Table 1; one skin layer (A) of a blend of 85 wt % Natureworks® PLA4032D and 15 wt % Natureworks® PLA4060D and antiblock masterbatch on one side of the core layer (B) as detailed in the Examples; and the heat sealable layer with antiblock (C) on the side of the core layer (B) opposite the skin layer (A) as detailed in Examples; via coextrusion through a die, cast on a chill drum using an electrostatic pinner, oriented in the machine direction at about 3 times through a series of heated and differentially sped rolls, followed by transverse direction stretching in a tenter oven. An optional amount of DuPont Biomax® 120 can be added to the core layer (B) in an amount of 2-4 wt % of the core layer which acts as a process aid during transverse orientation and is recommended if transverse orientation rates are greater than about 5 times, e.g. 6× or more. (If the transverse orientation rate is 5× or less, the Biomax 120 can be omitted). In the Examples for this application, the Biomax® 120 was omitted.

The multilayer coextruded BOPLA film was coextruded at processing temperatures of ca. 190° C. to 215° C. through a die and cast onto a cooling drum whose surface temperature was controlled between 15° C. and 26° C. to solidify the non-oriented laminate sheet at a casting speed of about 8-13 mpm. The non-oriented laminate sheet was preheated in the machine direction orienter at about 43° C. to 63° C., stretched in the longitudinal direction at about 55° C. to 60° C. at a stretching ratio of about 3 times the original length and the resulting stretched sheet was annealed at about 32° C. to 46° C. to reduce heat shrinkage and to obtain a uniaxially oriented laminate sheet. The uniaxially oriented laminate sheet was introduced into a tenter at a linespeed of ca. 24 to 60 mpm and preliminarily heated between about 65° C. and 75° C., and stretched in the transverse direction at about 75° C. to 85° C. at a stretching ratio of about 5 times the original width and then heat-set or annealed at about 100° C. to 120° C. to reduce internal stresses due to the orientation and minimize shrinkage and give a relatively thermally stable biaxially oriented sheet. TD orientation rates were adjusted by moving the transverse direction rails in or out per specified increments based on the TD infeed rail width settings and width of the incoming machine-direction oriented film. The biaxially oriented film has a total polyweight thickness between 10 and 100 μm, preferably between 15 and 30 μm, and most preferably between 17 and 25 μm.

After biaxial orientation, the polyweight thickness of the coextruded film overall was nominal 70 G (17.5 μm); the sealant layer (C) was nominal 8 G (2.0 μm); the skin layer (A) was nominal 4 G (1.0 μm); and the core layer was nominal 58 G (14.5 μm). Main layer extruder output was adjusted to maintain finished film polyweight thickness of 70 G (17.5 μm) after orientation as needed. The film was heat-set or annealed in the final zone of the tenter oven to reduce, internal stresses and minimize heat shrinkage of the film and maintain a dimensionally stable biaxially oriented film. The side of the core layer opposite the sealable skin layer was treated via corona discharge treatment method after orientation. The BOPLA multi-layer film was wound in roll form.

The core layer (B), which was comprised substantially of Natureworks® PLA4032D and PLA4060D, can also optionally include an amount of Biomax® 120 processing aid at 1.0 to 5.0 wt % of the core layer. The addition of Biomax® 120 can help reduce internal stresses during orientation, particularly transverse orientation. The use of this processing aid can enable transverse orientation rates in excess of 4-5 TDX, up to 8 and up to 10.5 TDX has been achieved. By using this processing aid, it may be possible to improve productivity of making oriented PLA films. An optional amount of amorphous PLA4060D, up to 20 wt % of the core layer may also be added. This may be desirable to do to reduce brittleness of the biaxially oriented film. A preferred amount was about 15 wt % PLA4060D in the core layer.

For cavitation, an amount of cavitating agent was added to the core layer. For PS and COC polymeric cavitators, these resins were blended directly into the core layer via resin blending systems which mixed the desired amount with the PLA resins. Amounts of PS or COC ranged from 2-10 wt % of the core, and preferably, 2.5-5.0% wt of the core. Crystalline polystyrene grade used was Ineos Nova™ LLC grade 1600, melt flow rate=6 g/10 min, Vicat softening temperature 106° C., specific gravity=1.04. Cyclic olefin copolymer grades used were Topas® Advanced Polymers grade 7010X1T3, melt volume rate=12 cm³/10 min at 230° C., Tg=78° C., density=1.02; and Topas® Advanced Polymers grade 8007F-400, melt volume rate=11 cm³/10 min at 230° C., Tg=78° C., density=1.02.

For mineral cavitators, a masterbatch was used and blended into the core layer via the same resin blending method, and masterbatch amounts ranged from 5-30 wt % of the core, preferably 10-20 wt % of the core. The calcium carbonate masterbatch used was Marval Industries, Inc. 166898 Natural PLA-CF30 masterbatch of 30 wt % 1.4 μm CaCO₃ in Natureworks® 4032D crystalline PLA carrier resin. The talc masterbatch used was Marval Industries, Inc. 167149 Natural PLA-TF20 masterbatch of 20 wt % 2.0 μm talc in Natureworks® 4032D crystalline PLA carrier resin. Depending on the loading of the mineral, the active mineral ranged from 1.5-9.0 wt % of the core layer if the Marval CF-30 CaCO₃ 30 wt % masterbatch was used; if the Marval TF-20 talc 20 wt % masterbatch was used, the active mineral ranged from 1.0-6.0 wt % of the core layer.

Without being bound by any theory, it is believed that when the inventive film is biaxially oriented, particularly at relatively low transverse orientation temperatures and certain machine direction orientation rates, cavitation occurs around the crystalline polystyrene domains within the core layer. Some work is required to develop the proper conditions to induce the required amount of cavitation to impart a white opaque cavitated appearance depending on the type and design of the film orientation line, but this can be found as a result of optimization of the respective line's process conditions. For a given cavitating agent the degree of cavitation imparts the opaque appearance of the film: at a low degree of cavitation, the film has a lower opaque appearance; at a higher degree of cavitation, the film has a higher opaque appearance due to increased number and/or size of voids. This cavitation has been observed by changes in measurement of the film's density (Table 1). As the film becomes more cavitated, its density decreases and its apparent thickness will increase due to the lofting affect of cavitation.

The sealable skin layer (C), which was comprised substantially of amorphous PLA Natureworks® PLA4060D, can also optionally include an amount of Mizusawa Silton® JC-30 3 um antiblock masterbatch of ca. 6% by weight of layer (C) to give an amount of antiblock loading of the sealant layer of about 3000 ppm.

The skin layer (A)—which can be used as a metal receiving layer or print receiving layer or laminating layer—can be comprised substantially of Natureworks® PLA4060D amorphous PLA and can also include blends of amorphous and crystalline PLA such as Natureworks® PLA4032D. Amounts of crystalline PLA can be up to 100 wt % of this layer (i.e. amorphous PLA can be 0-100 wt % of the layer (A)). Preferably, the amount of crystalline and amorphous PLA can be about 85 wt % and 15 wt % of the skin layer, respectively. Optionally, this layer can also include an amount of antiblock or antiblock masterbatch to control COF properties and aid in web handling. Typical amounts of inorganic antiblock can be up to 1000 ppm of the metal receiving layer (A) (preferably, 300-600 ppm) and can include silicas, aluminum magnesium calcium silicates, PMMA, or crosslinked silicone polymer of nominal 1.0-6.0 μm particle size, preferably 2.0-3.0 μm particle size. A preferred embodiment is to use this layer (A) as a metal receiving layer for metallization.

One embodiment is to metallize the discharge-treated surface opposite the heat sealable resin layer. The unmetallized laminate sheet is first wound in a roll. The roll is then placed in a vacuum metallizing chamber and the metal vapor-deposited on the discharge-treated metal receiving layer surface. The metal film may include titanium, vanadium, chromium, manganese, iron, cobalt, nickel, copper, zinc, aluminum, gold, or palladium, the preferred being aluminum. Metal oxides can also be contemplated, the preferred being aluminum oxide. The metal layer can have a thickness between 5 and 100 nm, preferably between 20 and 80 nm, more preferably between 30 and 60 nm; and an optical density between 1.5 and 5.0, preferably between 2.0 and 4.0, more preferably between 2.2 and 3.2. The test rolls were placed inside a vacuum chamber metallizer for vapor deposition metallization using aluminum which is well known in the art.

Optionally, prior to aluminum deposition, the film can be treated using a type of sputtering with a copper cathode at a linespeed of about 305 mpm. This treater is typically set up in the low vacuum section of the metallizer where the unwinding roll is located and the film is passed through this treater prior to entering the high vacuum section of the metallizer where the evaporation boats are located. The treater uses high voltage between the anode and cathode to produce free electrons. Oxygen gas is introduced into the treater and the free electrons combine with the oxygen gas to produce oxygen ions. Magnetic fields guide and accelerate the oxygen ions onto the copper cathode target which then emit copper ions. These copper ions are deposited onto the polylactic acid polymer substrate, creating a monolayer of copper, ca. 20 ng/m² (nanogram/sq. meter) thick. The film was then passed into the high vacuum deposition chamber of the metallizer which was metallized using aluminum to a nominal optical density target of 2.4. Optical densities for aluminum deposition can range from 2.0 to 5.0; preferably the OD range is 2.2-2.6. The metallized rolls were then slit on a film slitter and tested for oxygen and moisture gas permeability, optical density, metal adhesion, metal appearance and gloss, heat seal performance, tensile properties, thermal dimensional stability, and can be made into a laminate structure.

This invention will be better understood with reference to the following examples, which are intended to illustrate specific embodiments within the overall scope of the invention.

### Example 1

A 3-layer PLA film was made by the process described above using a core layer (B) formulation of 5 wt % Ineos 1600 polystyrene, 81 wt % PLA4032D and 14 wt % PLA4060D of the core layer. The non-sealable layer (A) consisted of 84.4 wt % PLA4032D, 15 wt % PLA4060D, and 0.6 wt % of JC30 antiblock PLA masterbatch. The sealant layer (C) consisted of 94 wt % PLA4060D and 6 wt % JC-30 masterbatch.

The total polyweight thickness of this film substrate after biaxial orientation was ca. 70 G or 0.70 mil or 17.5 μm. The thickness of the respective metal receiving layer after biaxial orientation was ca. 4 G (1.0 μm). The thickness of the respective heat sealable resin layer after biaxial orientation was ca. 8 G (2.0 μm). The thickness of the core layer after biaxial orientation was ca. 58 G (14.5 μm). The skin layers and the core layer were melt coextruded together through a flat die to be cast on a chill drum using an electrostatic pinner. The formed cast sheet was passed through a machine-direction orienter to stretch in the machine direction (MD) at ca. 3.0× stretch ratio in the longitudinal direction. This was followed by transverse direction (TD) stretching at ca. 5.0× stretch ratio in the tenter oven at a stretching temperature of about 175° F. (79.4° C.) and heat-set or annealed to reduce film shrinkage effects at ca. 240° F. (115° C.). The resultant biaxially oriented film was subsequently discharge-treated on the skin layer's surface opposite the heat sealable skin layer via corona treatment. The film was then wound up in roll form.

### Example 2

A process similar to Example 1 was repeated except that the core layer (B) blend was changed to: Ineos 1660 PS 2.5 wt %, PLA 4032D 83 wt %, and PLA 4060D 14.5 wt %.

### Comparative Example 1

A process similar to Example 1 was repeated except that the core layer (B) composition was changed to 85 wt % PLA 4032D and 15 wt % PLA4060D. No cavitating agent was added to the core.

### Comparative Example 2

A process similar to Example 1 was repeated except that the core layer (B) cavitating agent was changed to Topas® 7010X1T3 COC at 5 wt % of the core layer.

### Comparative Example 3

A process similar to Example 2 was repeated except that the core layer (B) cavitating agent was changed to Topas® 7010X1T3 COC at 2.5 wt % of the core layer.

### Comparative Example 4

A process similar to Example 1 was repeated except that the core layer (B) cavitating agent was changed to Topas® 8007F-400 COC at 5 wt % of the core layer.

### Comparative Example 5

A process similar to Example 2 was repeated except that the core layer (B) cavitating agent was changed to Topas® 8007F-400 COC at 2.5 wt % of the core layer.

### Comparative Example 6

A process similar to Example 1 was repeated except that the core layer (B) formulation was changed to: Cavitating agent 20 wt % Marval CF-30 CaCO₃ masterbatch (i.e. 6.0 wt % active CaCO₃); 68 wt % PLA 4032D; and 12 wt % PLA 4060D.

### Comparative Example 7

A process similar to Example 1 was repeated except that the core layer (B) formulation was changed to: Cavitating agent 25 wt % Marval TF-30 talc masterbatch (i.e. 5.0 wt % active talc); 64 wt % PLA 4032D; and 11 wt % PLA 4060D.

The following Tables 1 and 2 illustrate the properties of these examples:

TABLE 1

| | Core Layer (B) Composition wt % | | | | Light | | | |
|---|---|---|---|---|---|---|---|---|
| | Cavitating | PLA | PLA | Haze | Trans | | Density | Yield |
| Example | Agent | 4032D | 4060D | % | % | Gloss | g/cm3 | in²/lb |
| Ex. 1 | 5 | 81 | 14 | 97 | 77 | 62 | 1.15 | 34,385 |
| | 1600 PS | | | | | | | |
| Ex. 2 | 2.5 | 83 | 14.5 | 97 | 85 | 79 | 1.19 | 33,229 |
| | 1600 PS | | | | | | | |
| CEx. 1 | 0 | 85 | 15 | 13 | 93 | 135 | 1.24 | 31,889 |
| CEx. 2 | 5 | 81 | 14 | 95 | 66 | 87 | 1.14 | 34,686 |
| | 7010X1T3 | | | | | | | |
| | COC | | | | | | | |
| CEx. 3 | 2.5 | 83 | 14.5 | 97 | 76 | 89 | 1.16 | 34,088 |
| | 7010X1T3 | | | | | | | |
| | COC | | | | | | | |
| CEx. 4 | 5 | 81 | 14 | 93 | 84 | 97 | 1.19 | 33,229 |
| | 8007F-400 | | | | | | | |
| | COC | | | | | | | |
| CEx. 5 | 2.5 | 83 | 14.5 | 90 | 86 | 99 | 1.20 | 32,952 |
| | 8007F-400 | | | | | | | |
| | COC | | | | | | | |
| CEx. 6 | 20 | 68 | 12 | 98 | 62 | 62 | 1.08 | 36,613 |
| | CF-30 | | | | | | | |
| | CaCO₃ | | | | | | | |
| CEx. 7 | 25 | 64 | 11 | 96 | 84 | 81 | 1.12 | 35,306 |
| | TF-20 talc | | | | | | | |

TABLE 2

| | | | | | | Ult | Heat | | |
|---|---|---|---|---|---|---|---|---|---|
| | Core Layer (B) Composition wt % | | | Modulus | Elongation | Strength | Shrink | | |
| | Cavitating | PLA | PLA | MD/TD | MD/TD | MD/TD | MD/TD | O₂TR | MVTR |
| Example | Agent | 4032D | 4060D | kpsi | % | kpsi | % | cc/m² | g/m² |
| Ex. 1 | 5 | 81 | 14 | 446/577 | 121/88 | 13.9/24.4 | 10.0/10.5 | 3.80 | 1.07 |
| | 1600 PS | | | | | | | | |
| Ex. 2 | 2.5 | 83 | 14.5 | 480/651 | 138/94 | 16.9/26.3 | 9.0/10.0 | 4.73 | 1.19 |
| | 600 PS | | | | | | | | |
| CEx. 1 | 0 | 85 | 15 | 504/650 | 149/110 | 20.9/30.4 | 6.5/7.5 | 8.74 | 2.19 |
| CEx. 2 | 5 | 81 | 14 | 451/519 | 115/73 | 14.9/14.7 | 8.5/9.0 | 5.60 | 1.36 |
| | 7010X1T3 | | | | | | | | |
| | COC | | | | | | | | |
| CEx. 3 | 2.5 | 83 | 14.5 | 450/572 | 112/86 | 15.2/20.1 | 8.0/8.5 | 6.14 | 1.20 |
| | 7010X1T3 | | | | | | | | |
| | COC | | | | | | | | |
| CEx. 4 | 5 | 81 | 14 | 467/591 | 146/111 | 16.6/27.9 | 9.0/10.5 | 4.14 | 1.26 |
| | 8007F-400 | | | | | | | | |
| | COC | | | | | | | | |
| CEx. 5 | 2.5 | 83 | 14.5 | 469/581 | 153/73 | 18.1/15.7 | 9.5/10.0 | 3.82 | 0.82 |
| | 8007F-400 | | | | | | | | |
| | COC | | | | | | | | |
| CEx. 6 | 20 | 68 | 12 | 223/293 | 4/57 | 9.2/13.8 | 6.0/5.5 | NA | NA |
| | CF-30 | | | | | | | | |
| | CaCO₃ | | | | | | | | |
| CEx. 7 | 25 | 64 | 11 | 229/308 | 112/62 | 14.2/18.0 | 8.5/12.0 | NA | NA |
| | TF-20 talc | | | | | | | | |

As Tables 1 and 2 show, Comparative Example 1 (CEx 1), which is a control film of a non-cavitated biaxially oriented PLA film with a nearly 100 wt % amorphous PLA sealant layer (C) showed the highest density and lowest yield of the Examples. It also showed high clarity or low opacity (low haze and high light transmission), and high gloss. These optical properties are due to the fact that this example is non-cavitated and remained a transparent, glossy film. Tensile properties were the highest for this example, as might be expected, since it is a solid, non-voided film. Similarly, thermal shrinkage was also the lowest. After metallizing, gas barrier properties were poorest of the examples.

Examples 1 and 2 (Ex 1 and Ex 2) added 5 wt % and 2.5 wt % respectively of polystyrene to the core layer as a cavitating agent. The film became white opaque as demonstrated by high haze and low light transmission values. The gloss also dropped due to rougher surface caused by cavitation of the core layer. However, density was lower and yield higher than CEx. 1 due to the cavitation, and especially improved density and yield was noted in Ex. 1 with the higher loading of PS. Tensile properties were lower than CEx. 1 but still very good, indicating retention of good mechanical properties of the cavitated film. Thermal stability was worsened however, but could probably be improved with optimization of annealing conditions. Surprisingly, moisture and oxygen barrier properties were significantly improved over CEx. 1.

Comparative Examples 2 and 3 (CEx 2 and CEx 3) added 5 wt % and 2.5 wt % respectively cyclic olefin copolymer grade 7010X1T3 to the core layer as a cavitating agent. Results for optical properties, density, yield, tensile properties, were comparable to Examples 1 and 2. Gas barrier properties were also surprisingly improved over CEx 1 and comparable to Examples 1 and 2.

Comparative Examples 4 and 5 (CEx 4 and CEx 5) added 5 wt % and 2.5 wt % respectively cyclic olefin copolymer grade 8007F-400 to the core layer as a cavitating agent. Results for optical properties, density, yield, tensile properties, however, were not as good as Examples 1 and 2, nor with CExs 2 and 3. It appears that this grade of COC was not as effective as the COC grade used in CExs 2 and 3, nor as good as the PS used in Exs 1 and 2. Gas barrier properties were still surprisingly improved over CEx 1 and comparable to Examples 1 and 2.

Comparative Example 6 (CEx 6) used 20 wt % of a calcium carbonate masterbatch added to the core layer as a cavitating agent. The active CaCO₃ was 6 wt % of the core layer. The film had high opacity, low gloss, and the lowest density/highest yield of the Examples. However, mechanical properties were very poor and during film-making, many film breaks were observed indicating a weak and easily tearable film. In fact, the MD elongation and ultimate strength of this example was so low that the film could not be metallized due to the film tearing. The very poor mechanical properties may have been due to very large voids being formed within the core layer.

Comparative Example 7 (CEx 7) used 25 wt % of a talc masterbatch added to the core layer as a cavitating agent. The active talc was 5 wt % of the core layer. The film had high opacity, low gloss, and also demonstrated low density/high yield comparable to CEx 6. CEx 7's mechanical properties were better than CEx 6, but still poorer than Exs 1 and 2.

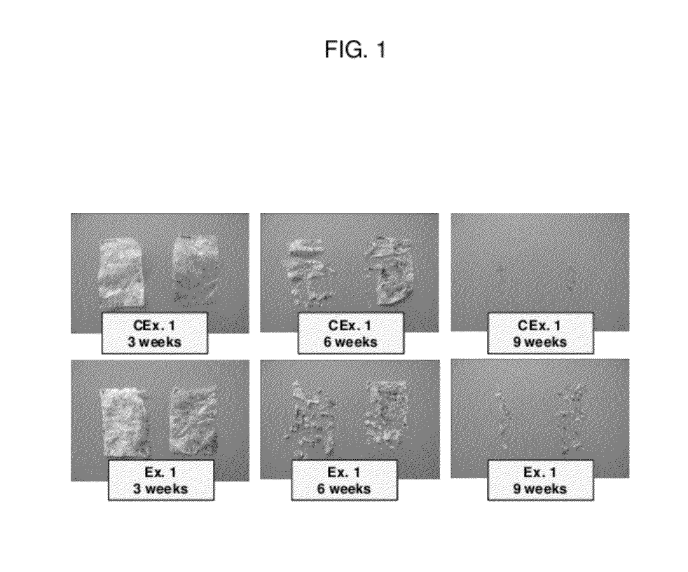

FIG. 1 shows compostability studies of Ex 1 and CEx 1 in a mulch medium at 58° C. for several weeks substantially in accordance with ASTM D6400. The study-to-date of the time of this writing indicated that compostability and degradability of cavitated Ex 1 with polystyrene cavitating agent is comparable to that of uncavitated CExl without any polystyrene after 9 weeks of composting.

In conclusion, the use of crystalline polystyrene as a cavitating agent can be an effective method to cavitate PLA films to obtain attractive white opaque films with lower density and higher yield. Mechanical properties of the film can also be maintained adequately compared to non-cavitated PLA film and much better than mineral-based cavitating agents. Indeed, the use of PS cavitating agents provide properties that are comparable to that of COC cavitating agents but can be achieved by much lower raw material cost as PS is less expensive and more cost-effective than COC.

### Test Methods

The various properties in the above examples were measured by the following methods:

Transparency of the film was measured by measuring haze of a stack of 8 sheets of film using a hazemeter model like a BYK Gardner “Haze-Gard Plus®” substantially in accordance with ASTM D1003.

Gloss of the film was measured by measuring the desired side of a single sheet of film via a surface reflectivity gloss meter (BYK Gardner Micro-Gloss) substantially in accordance with ASTM D2457. The A-side was measured at a 60° angle; the C-side or sealant layer side was measured at a 20° angle.

Light transmission of the film was measured by measuring light transmission of a single sheet of film via a light transmission meter (BYK Gardner Haze-Gard Plus) substantially in accordance with ASTM D1003.

Film density was calculated by taking a stack of 10 sheets (letter paper size e.g. 8.5 inches by 11 inches) of film and cutting them via a die of area 33.69 cm2 and weighing the cut sheets on an analytical scale. The 10 sheets are also measured for thickness using a flat-head micrometer to get an average thickness of the film. The measured weight and thickness is then used in a calculation to obtain density:

Weight (g)=Density (g/cm³) Thickness (cm)×area (cm²)

Film yield is calculated using film density and thickness by the following formula:

$$\frac{453.59}{Density ( g \text{/} {cm}^{3} ) \times {( 2.54 )}^{3} \times thickness ( inches )} = Yield ( in 2 \text{/} lb )$$

Tensile properties such as Young's modulus, ultimate strength, and elongation are measured substantially in accordance with ASTM.

Moisture transmission rate of the film was measured by using a Mocon Permatran 3/31 unit substantially in accordance with ASTM F1249. In general, preferred values of MVTR would be less than 5 g/m²/day at 38° C. and 90% relative humidity, and preferably less than 1.5 g/m²/day.

Oxygen transmission rate of the film was measured by using a Mocon Oxtran 2/20 unit substantially in accordance with ASTM D3985. In general, preferred values of O₂TR would be equal or less than 46.5 cc/m²/day and preferably 30 cc/m²/day or less at 23° C. and 0% relative humidity.

Compostability and degradability of the test films were measured substantially in accordance with ASTM procedure D-6400 “Compostable Plastics,” sub-group procedure D-5338 “Disintegration Test.” This ASTM procedure is also known as ISO 1629 in the International Standards test procedures. In essence, the test films are aged under composting conditions of 58° C. for 180 days maximum duration in a compost medium and films are observed and rated for disintegration. Preferably the test films would degrade completely within 180 days (26 weeks) and more preferably, within 105 days (15 weeks).

This application discloses several numerical ranges in the text and figures. The numerical ranges disclosed inherently support any range or value within the disclosed numerical ranges even though a precise range limitation is not stated verbatim in the specification because this invention can be practiced throughout the disclosed numerical ranges.

The above description is presented to enable a person skilled in the art to make and use the invention, and is provided in the context of a particular application and its requirements. Various modifications to the preferred embodiments will be readily apparent to those skilled in the art, and the generic principles defined herein may be applied to other embodiments and applications without departing from the spirit and scope of the invention. Thus, this invention is not intended to be limited to the embodiments shown, but is to be accorded the widest scope consistent with the principles and features disclosed herein. Finally, the entire disclosure of the patents and publications referred in this application are hereby incorporated herein by reference.

1. A biaxially oriented polylactic acid polymer film comprising:
a layer comprising polylactic acid resin and 2.0-10.0 wt % crystalline polystyrene.

2. The film of claim 1, wherein the layer comprising polylactic acid resin and crystalline polystyrene has a plurality of voids and cavities and a density of less than 1.24.

3. The film of claim 1, wherein the film has a white opaque appearance.

4. The film of claim 1, further comprising a metal layer on one side of the layer comprising polylactic acid resin and crystalline polystyrene.

5. The film of claim 4, wherein the metal layer has an optical density of 2.0-4.0.

6. The film of claim 4, wherein the metal layer comprises aluminum.

7. The film of claim 4, wherein the film has an oxygen gas barrier of less than 46.5 cc/m²/day and moisture vapor barrier of less than 5 g/m²/day.

8. The film of claim 4, wherein the film has an oxygen gas barrier of less than 10 cc/m²/day and moisture vapor barrier of less than 1.5 g/m²/day.

9. A biaxially oriented multilayer film comprising:
a first layer comprising an amorphous polylactic acid resin; and
a second layer comprising crystalline polylactic resin and crystalline polystyrene.

10. A biaxially oriented multilayer film comprising:
a first heat sealable layer comprising an amorphous polylactic acid resin; and
a second layer comprising crystalline polylactic resin and crystalline polystyrene.

11. The multilayer film of claim 10, wherein the second layer comprises 2.0-10.0 wt % crystalline polystyrene.

12. The multilayer film of claim 10, wherein the second layer further comprises 2-10 wt % ethylene-acrylate copolymer.

13. The multilayer film of claim 10, wherein the second layer further comprises inorganic antiblock particles selected from amorphous silicas, aluminosilicates, sodium calcium aluminum silicates, crosslinked silicone polymers, and polymethylmethacrylates.

14. The multilayer film of claim 10, wherein the second layer further comprises amorphous polylactic acid resin.

15. The multilayer film of claim 10, further comprising a third layer comprising polylactic acid on a side of the second layer opposite the first layer.

16. The multilayer film of claim 10, further comprising a metal layer.

17. The multilayer film of claim 16, wherein the metal layer has an optical density of 2.0-4.0.

18. The multilayer film of claim 16, wherein the film has an oxygen gas barrier of less than 46.5 cc/m²/day and moisture vapor barrier of less than 5 g/m²/day.

19. The multilayer film of claim 16, wherein the film has an oxygen gas barrier of less than 10 cc/m²/day and moisture vapor barrier of less than 1.5 g/m²/day.

20. A method of making a biaxially oriented polylactic acid polymer film comprising:
extruding a film comprising a layer comprising polylactic acid resin and 2.0-10.0 wt % crystalline polystyrene; and
biaxially orienting the film.

21. A method of making a biaxially oriented multilayer film comprising:
co-extruding a film comprising a first heat sealable layer comprising an amorphous polylactic acid resin, and a second layer comprising crystalline polylactic resin and crystalline polystyrene; and
biaxially orienting the film.

22. The method of claim 21, wherein the second layer further comprises 2-10 wt % ethylene-acrylate copolymer.

23. The method of claim 21, wherein the film has a machine direction orientation rate of 2.0-3.0× and transverse direction orientation rate of 8.0-11.0×.

24. The method of claim 21, wherein the second layer comprises 2.0-10.0 wt % crystalline polystyrene.

25. The method of claim 21, wherein the second layer further comprises inorganic antiblock particles selected from amorphous silicas, aluminosilicates, sodium calcium aluminum silicates, crosslinked silicone polymers, and polymethylmethacrylates.

26. The method of claim 21, wherein the second layer further comprises amorphous polylactic acid resin.

27. The method of claim 21, further comprising coextruding a third layer comprising polylactic acid on a side of the second layer opposite the first layer.

28. The method of claim 21, further comprising vapor depositing a metal layer on a surface of the film.

29. The method of claim 28, wherein the metal layer has an optical density of 2.0-4.0.
